(19) United States
(12) Patent Application Publication
(10) Pub. No.: US 2002/0094587 A1
(43) Pub. Date: Jul. 18, 2002

(54) Method for forming capacitor having lower electrode formed by iridium/platinum layer

(76) Inventors: Kwon Hong, Ichon-shi (KR); Ho Jin Cho, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/081,836

(22) Filed: Feb. 21, 2002

Related U.S. Application Data
(63) Continuation of application No. 09/343,173, filed on Jun. 29, 1999.

(30) Foreign Application Priority Data
Jun. 29, 1998 (KR) 1998-24704

(51) Int. Cl. H01L 21/00; H01L 21/8242

(52) U.S. Cl. 438/3; 438/239; 438/240

(57) ABSTRACT

There is provided a method for forming a capacitor of a semiconductor device capable of improving an oxygen diffusion prevention characteristic and preventing leak current from increasing. The invention is characterized that a lower electrode is formed from a double layer comprising a Pt film and Ir film in forming a dielectric layer having a high dielectric characteristic on a lower electrode.

### BACKGROUND OF THE INVENTION

The present invention relates to semiconductor manufacturing, and more particularly, in forming a capacitor having a dielectric layer deposited at high temperature in oxygen containing ambient.

To increase capacitance of a capacitor included in high density DRM devices, a (Ba, Sr)TiC₃ film having a high dielectric characteristic is used to the dielectric layer of a capacitor.

FIG. 1 is a section view showing the process according to the prior art. As illustrated FIG. 1, by selectively etching an insulated layer 11 formed on a semiconductor surface 10, a contact hole exposuring the semiconductor substrate 10 is formed, after that a polyslicon plug 12 is formed in the contact hole. Then, a titanium(Ti) film 13 and titanium nitride(TiN) l4 are formed to prevent silicon from diffusing from the polysilicon plug 12 to the lower electrode of a capacitor, and platinum(Pt) film 15 constructing a lower electrode of a capacitor is formed on the TiN film 14. Ther, patterning the Pt film 15, TiN film 14, and Ti film 13 forms a diffusion barrier pattern and a lower electrode pattern, after that a (Ba, Sr)Ti₃ dielectric layer 16 and a Pt upper electrode 17 are formed on the lower electrode.

Since a (Ea, Sr)TiO₃ film is deposited at hich temperature in oxygen containing ambient, a lower electrode must have a good oxygen diffusion prevention characteristic. However, since the Pt film being used to a lower electrode doesn't have an oxygen diffusion prevention characteristic, there is a problem that a nitride system film being used to a diffusion barrier of polysilicon, such as TiN, TaN, WN, is oxidized. To solve the problems, an iridium(Ir) film is formed instead of a Pt film, and oxidizing the Ir film at temperature of more than 450° C. forms an iridium oxide(IrO₂)film having a good oxygen diffusion prevention characteristic as a lower electrode. However, oxidized electrodes, such as IrO₂ film, are tended to increase leak current due to a small difference of work function with a (Be, Sr)TiO₃ film.

### SUMMARY OF THE INVENTION

An object of the present invention is to provide a method for forming a capacitor of a semiconductor device capable of improving an oxygen diffusion prevention characzeristic and preventing leak current from increasing.

In accord with the object cf the present invention, there is provided a method for forming a capacitor of a semiconductor device comprising the steps of: forming a polysilicon plug on a semiconductor substrate; forming a diffusion barrier comprising a titanium(Ti) film and titanium nitride(TiN) on the polysilicon plug; sequentially depositinc an iridium1r) film and a platinum(Pt) film on the diffusion barrier; patterning the diffusion barrier, the Ir film, and the Pt film, and forming a lower electrode; forming a dielectric layer on the Pt film at high temperature in oxygen containing ambient; and forming an upper electrode on the dielectric layer.

The present invention is characterized that the lower electrode of a capacitor having a dielectric layer formed at high temperature in oxygen containing ambient is formed from a double layer comprising an Ir film and Pt film, whereby it can prevent oxygen from diffusing and prevent leak current from increasing in depositing a dielectric layer at hig.h temperature in oxygen containing ambient.

### BRIEF DESCRIPTION OF THE DRAWING

The object, features and advantages of the present invention are understood within the context of the description of the preferred embodiment as set forth below. The description of the preferred embodiment is understood within the context Pf accompanying drawino. Which form a material part of this disclosure, wherein:

FIG. 1 is a section view showing the process according to a prior art;

FIG. 2A-2D are section views showing the process according to the present invention.

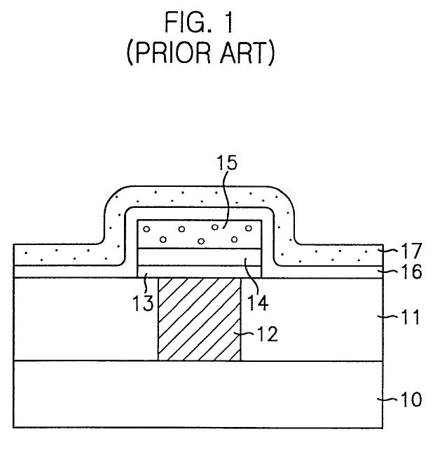

### DESCRIPTION OF THE PREFERRED EMBODIMENT

The description of the preferred embodiment as set forth below.

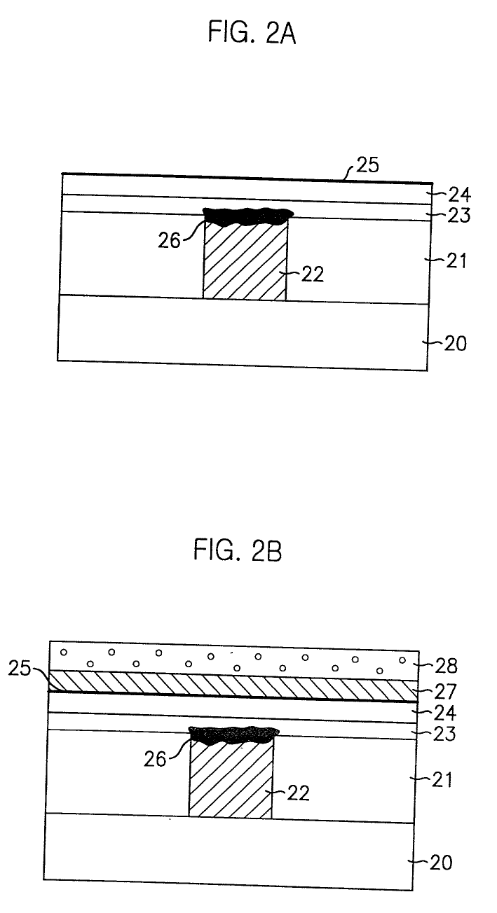

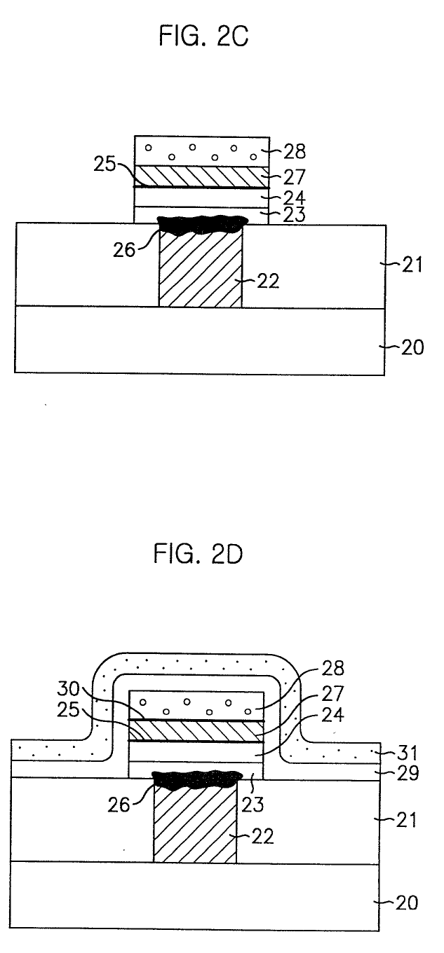

FIG. 2A to FIG. 2D are section views showing the capacitor forming processes of an embodiment of the present invention.

As illustrated to FIG. 2A, by selectively etching an insulated layer 21 on a semiconductor substrate 20, a contact hole exposuring the semiconductor substrate 20 is formed, and a polysilicon film is formed on the whole structure in range of 500Å-3000Å thick by chemical vapor deposition. Then, the polysilicon film is polished by chemical mechanical polishing to form a polysilicon plug 22 in the contact hole.

Then, a Ti film 23 and TiN film 24 constructing a diffusion barrier are formed on the whole structure by a sputtering method. It is preferable that the Ti film 23 and TiN film 24 have a thickness of 200Å-300Å and 500Å-1000Å respectively. Then, a rapid thermal process is performed at temperature of 600° C.-700° C. in oxygen containing ambient for 10-30 seconds, so that a TiSiₓ film 26 is formed on the boundary of the Ti film 23 and the polysilicon pluo 22 and a TiNO film 25 is formed on the TiN film 24. The TiNlO film 25 prevents silicon from diffusing from the polysilicon pluc 22 to the lower electrode of a capacitor.

Then, as illustrated Fic. 2B, ar Ir film 27 and a first Pt film 28 are sequentially formed on the TiNC film 25. The Ir film 27 is formed by sputterino in range of 100Å-500Å thick for preventing the TiN film 24 from being oxidized, and the first Pt film 28 is formed by sputtering at temperature of 500° C. -600° C. in range of 500Å-1000Å thick.

Then, as illustrated FIG. 2C, the first Pt film 28, Ir film 27, TiNO film 25, TiN film 24, and Ti film 23 are patterned to form a diffusion barrier pattern consisting of the TiNO film 25, TiN film 24, and Ti film 23 and a lower electrode pattern consisting of the first Pt film 28 and Ir film 27.

Then, as illustrated FIG. 2D, a (Ba, Sr)TiO. film 2O having a high dielectric characteristic is deposited on the whole structure which the diffusion barrier and the lower electrode pattern have been completed a. hich temperature in oxygen containing ambient. Namely, the film 29 is deposited by a metal organic chemical vapor deposition(MOCVD) method at temperature of 400° C.-650° C., the thickness of the film is preferable in range of 100Å-1000Å. When the (Ba, Sr)TiC₃ film 29 is deposited at high temperature in oxygen containing ambient, the oxygen dif. used through the first Pt film 28 reacts with the Ir film 27, whereby, an IrO₂ Gilm 30 is formed on the interlaver of the Ir film 27 and the Pt film 28. Thus, it can prevent the TiN film 24 from being oxidized.

Then, a second Pt film 31 is formed on the (Ba, Sr)Tio₃ film 29, after that the second Pt film 31 and the (BEa, Sr)Ti₃. film 29 is patterned to form a capacitor.

As described above, in forminc a dielectric layer having a high dielectric characteristic or. a lower electrode, the lower electrode is formed from a double layer consistinc of a Pt film and Ir film. Accordingly, as the oxycen diffuses throuoh the Pt film reacts with the Ir film, the nitride system film under the Ir film can be prevented from being nitrated, also, as the Pt film is located at interlayer of the dielectric layer and iridium oxide, leak current does not increase, so reliability of a oevice is improved.

Although a preferred embodiment of the present invention has been illustrated and described, various alternatives, modifications and equivalents may be used. Thereore, the foregoing description should not be taken as limiting the scope of the present invention which is defined by the appended claims.

What is claimed is:

1. A method for forming a capacitor of a semiconductor device comprising the steps of:
forming a polysilicon plug on a semiconductor substrate;
forming a diffusion barrier comprising a titanium (Ti) film and a titanium nitride (TiN) film on the polysilicon plug;
applying a rapid thermal process to the titanium nitride (TiN) film so that a titanium oxynitride (TiNO) film is formed on the titanium nitride film and a titanium silicide film is formed on the polysilicon plug;
depositing an iridium (Ir) film and a platinum (Pt) film on the diffusing barrier;
patterning the diffusion barrier, the Ir film, and the PT film, and forming a lower electrode;
forming a dielectric layer on the Pt film at high temperature in an oxygen atmosphere and simultaneously forming an iridium oxide film between the iridium film and the platinum film; and
forming an upper electrode on the dielectric layer.

2. The method of claim 1, wherein the rapid thermal process is performed at temperature of 600° C.-700° C. for 10-30 seconds.

3. The method of claim 1, wherein the dielectric layer is formed from a (Ba, Sr) TiO₃ film.

4. The method of claim 3, wherein the (Ba, Sr) TiO₃ film is formed by a metal organic chemical vapor deposition (MOCVD) method at temperature of 400° C.-650° C. in range of 100Å-1000Å thick.

5. The method of claim 1, wherein the Ir film is formed by a sputtering method in the range of 100Å-500Å thick.

6. The method of claim 1, wherein the Pt film is formed by a sputtering method at temperature of 500° C.-600° C. in the range of 500Å-1000Å thick.

7. The method of claim 1, wherein the upper electrode is formed from a Pt film having a thickness of 500Å-3000Å.
